(19) United States
(12) Patent Application Publication
(10) Pub. No.: US 2025/0237689 A1
(43) Pub. Date: Jul. 24, 2025

(54) SYSTEM AND METHOD FOR DETERMINING WHETHER TO REPLACE ION FILTER

(71) Applicants: Hyundai Motor Company, Seoul (KR); Kia Corporation, Seoul (KR)

(72) Inventors: Wook Il JANG, Yongin-Si (KR); Jong Gyun Kim, Yongin-Si (KR); Sung Ho Park, Suwon-Si (KR); Min Taek Kim, Seoul (KR); Won Jung Kim, Hwaseong-Si (KR); Seung Min Noh, Seoul (KR); Soon Hwan Kim, Yongin-Si (KR); Kyu Nam Chol, Incheon (KR); Jae Won Jang, Busan (KR)

(73) Assignees: Hyundai Motor Company, Seoul (KR); Kia Corporation, Seoul (KR)

(21) Appl. No.: 18/677,527

(22) Filed: May 29, 2024

(30) Foreign Application Priority Data
Jan. 22, 2024 (KR) 10-2024-0009237

(51) Int. Cl. G01R 31/14; H01M 8/04029; H01M 8/04044; H01M 8/04537

(52) U.S. Cl. CPC G01R 31/14; H01M 8/04029; H01M 8/04044; H01M 8/04649; H01M 2250/20

(57) ABSTRACT

In a system for determining whether to replace an ion filter, the system includes a measurement unit configured for measuring an insulation resistance value of a fuel cell stack while a vehicle or a system is in operation, and a controller operatively connected to the measurement unit and configured to determine whether to replace the ion filter based on the insulation resistance value. Here, with one cycle from start to end of operation of the vehicle or the system, the controller is configured to determine a movement value based on the insulation resistance value measured at each of cycles, wherein the movement value is a moving average or a moving median for an average value or a median value of the insulation resistance value, and the controller is configured to determine whether to replace the ion filter based on at least one of the size of the movement value or the change rate of the movement value.

### CROSS-REFERENCE TO RELATED APPLICATION

The present application claims priority to Korean Patent Application No. 10-2024-0009237, filed on Jan. 22, 2024, the entire contents of which is incorporated herein for all purposes by this reference.

### BACKGROUND OF THE PRESENT DISCLOSURE

### Field of the Present Disclosure

The present disclosure relates to a system and method for determining whether to replace an ion filter, wherein the system and method are configured for determining whether to replace the ion filter by processing measured insulation resistance values.

### Description of Related Art

A fuel cell is a type of power generation device that directly converts chemical energy generated by oxidation of fuel into electrical energy. A fuel cell is basically similar to a chemical cell in that they both use oxidation-reduction reactions. However, unlike the chemical cell, which carries out a cell reaction inside a closed system, the fuel cell differs from the chemical cell in that reactants are continuously supplied from the outside thereof and reaction products are continuously removed to the outside of the system. Recently, a fuel cell power generation system has been put into practical use, and because the reaction product of a fuel cell is pure water, research is being actively conducted to use a fuel cell as an energy source for an eco-friendly vehicle or a power generation system.

Generally, a fuel cell system includes a cooling system configured to control the temperature of the fuel cell and a drive system configured to drive a vehicle or power generation system using the fuel cell. The cooling system includes a pipe configured to circulate cooling water within the fuel cell and a radiator configured to control the temperature of the cooling water, and the drive system includes components configured to drive a motor provided in the vehicle or the system using electrical energy generated by the fuel cell.

Meanwhile, in the vehicle or the system to which the fuel cell system is applied (hereinafter, “fuel cell vehicle”), insulation resistance is generated, such as resistance caused by various electric components forming the fuel cell system and resistance caused by cooling water. The insulation resistance of the fuel cell system should be kept at or above a predetermined value for driver safety. Therefore, an ion filter is applied to the fuel cell system to remove ions in cooling water. Anion filter is a consumable that must be replaced after a predetermined period of time or when the operation time of the vehicle or the system increases. In replacing the ion filter, it is important to determine the precise replacement cycle, and for the present purpose, the insulation resistance of the fuel cell system or the electrical conductivity of the cooling water need to be measured.

However, the insulation resistance value may vary due to various reasons, such as failure of components, short circuit, and contamination of cooling water, in addition to a decrease in durability of the ion filter. For the present reason, when whether or not to replace the ion filter is determined based on the insulation resistance value, it is hard to figure out the precise replacement time of the ion filter. Moreover, when a sensor configured for measuring electrical conductivity is applied to the fuel cell system, the durability of the ion filter to remove ions from the cooling water may be directly checked, but the problem is that the sensor is relatively expensive.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a system and method for determining whether to replace an ion filter, wherein the system and method are configured for accurately determining whether replacement of the ion filter is necessary by measuring insulation resistance without having to use an electrical conductivity sensor.

Another object of the present disclosure is to provide a system and method for determining whether to replace an ion filter, wherein the system and method are configured for increasing reliability of decision on replacement of the ion filter by analyzing declining pattern of the durability of the ion filter and conducting reliability analysis on the declining pattern of the durability of the ion filter.

In one aspect, the present disclosure provides a system for determining whether to replace an ion filter. The system for determining whether to replace an ion filter may include a measurement unit configured for measuring an insulation resistance value of a fuel cell stack while a vehicle or a system is in operation, and a controller operatively connected to the measurement unit and configured to determine whether to replace the ion filter based on the insulation resistance value. Here, with one cycle from start to end of operation of the vehicle or the system, the controller may be configured to determine a movement value based on the insulation resistance value measured at each of cycles, wherein the movement value may be a moving average or a moving median for an average value or a median value of the insulation resistance value, and the controller may be configured to determine whether to replace the ion filter based on at least one of the size of the movement value or the change rate of the movement value.

In an exemplary embodiment of the present disclosure, the controller may be configured to determine whether a first condition for determining whether the size of the movement value is equal to or smaller than a preset threshold is satisfied and whether a second condition for determining whether the change rate of the movement value is smaller than a preset change rate is satisfied, and when the first condition and the second condition are satisfied, the controller may be configured to determine that the ion filter needs to be replaced.

In another exemplary embodiment of the present disclosure, the controller may be configured to count cases where the insulation resistance values measured in one cycle from the start to the end of operation of the vehicle or the system are within a predetermined range, may be configured to determine whether a third condition for determining whether the total count is greater than a preset counting value is satisfied, and in response that all of the first condition, the second condition, and the third condition are satisfied, the controller may be configured to determine that the ion filter needs to be replaced.

In yet another exemplary embodiment of the present disclosure, when the insulation resistance values measured in one cycle are equal to or smaller than a preset number, the controller may not determine whether the third condition is satisfied based on the insulation resistance values measured in the corresponding one cycle.

In yet another exemplary embodiment of the present disclosure, the controller may be configured to determine whether the total count of cases, the case in which the insulation resistance values measured at each of consecutive cycles are within the predetermined range, is greater than the preset counting value.

In still yet another exemplary embodiment of the present disclosure, the movement value may be determined based on expression values in which an average value or a median value of the insulation resistance values measured within one cycle is coded as a single digit number.

In a further exemplary embodiment of the present disclosure, five expression values may be stored by being converted into one 5-digit number, or ten expression values may be stored by being converted into one 10-digit number, or nineteen expression values may be stored by being converted into one 19-digit number.

In another further exemplary embodiment of the present disclosure, the expression values may be stored in a preset first number, the controller may be configured to determine the movement value based on the expression values stored in the preset first number, the controller may be configured to determine whether to replace the ion filter based on a consecutive preset second number of the movement values, and the preset first number may be greater than the preset second number.

In yet another further exemplary embodiment of the present disclosure, the controller may compare a latest movement value in the preset second number of the movement values or a size of an average of the movement values with a preset threshold to determine whether a first condition is satisfied.

In yet another further exemplary embodiment of the present disclosure, the controller may compare a difference between the latest movement value in the preset second number of the movement values and a decision value based on past movement values with a preset difference value to determine whether a second condition is satisfied.

In still yet another further exemplary embodiment of the present disclosure, when the difference between the latest movement value and the decision value is greater than the preset difference value, the controller may confirm that there is an error in measurement of the insulation resistance value and stop a process of determining whether to replace the ion filter for a predetermined time period.

In a still further exemplary embodiment of the present disclosure, the controller may compare a change rate of the preset second number of the movement values with a preset change rate to determine whether a second condition is satisfied.

In a yet still further exemplary embodiment of the present disclosure, the controller may be configured to determine the ion filter needs to be replaced only when the first condition and the second condition are satisfied.

In another aspect, the present disclosure provides a method of determining whether to replace an ion filter implemented by a controller operatively connected to the measurement unit and configured to determine whether to replace the ion filter. The method of determining whether to replace an ion filter may include determining an average value or a median value of insulation resistance values measured in one cycle from start to end of operation of a vehicle or a system, deriving a plurality of expression values in which the average value or the median value of the insulation resistance values measured at each of cycles is coded as a single digit number, determining a plurality of movement values for the expression values, and determining whether to replace the ion filter based on at least one of a size of at least one of the movement values or a change rate of the movement values. Here, the movement value may be a moving average or a moving median for an average value or a median value of the insulation resistance value.

In an exemplary embodiment of the present disclosure, the determining of whether to replace the ion filter may include determining whether a first condition for determining whether the size of the movement value is equal to or smaller than a preset threshold is satisfied and whether a second condition for determining whether the change rate of the movement value is smaller than a preset change rate is satisfied, and determining, when both the first condition and the second condition are satisfied, that the ion filter needs to be replaced.

In another exemplary embodiment of the present disclosure, the determining of whether to replace the ion filter may include counting cases where the insulation resistance values measured in one cycle from the start to the end of operation of the vehicle or the system are within a predetermined range, and determining whether a third condition for determining whether total count is greater than a preset counting value is satisfied, and determining, in response that all of the first condition, the second condition, and the third condition are satisfied, that the ion filter needs to be replaced.

In yet another exemplary embodiment of the present disclosure, the determining of the movement values may include determining the movement value based on a preset first number of the expression values, and determining whether to replace the ion filter based on a consecutive preset second number of the movement values.

In yet another exemplary embodiment of the present disclosure, the method may further include comparing a latest movement value in the preset second number of the movement values or a size of an average of the movement values with a preset threshold to determine whether a first condition is satisfied.

In still yet another exemplary embodiment of the present disclosure, the method may further include comparing a difference between the latest movement value in the preset second number of the movement values and a decision value based on past movement values with a preset difference value or comparing a change rate of the preset second number of the movement values with a preset change rate to determine whether a second condition is satisfied.

In yet another aspect, the present disclosure provides a storage medium configured to store computer-readable instructions, wherein the instructions are executed by a processor. The processor is configured to perform operations of determining an average value or a median value of insulation resistance values measured in one cycle from start to end of operation of a vehicle or a system, deriving a plurality of expression values in which the average value or the median value of the insulation resistance values measured at each of cycles is coded as a single digit number, determining movement values for the expression values, and determining whether to replace the ion filter based on at least one of a size of at least one of the movement values or a change rate of the movement values. Here, the movement value may be a moving average or a moving median for an average value or a median value of the insulation resistance value.

Other aspects and exemplary embodiments of the present disclosure are discussed infra.

It is to be understood that the term “vehicle” or “vehicular” or other similar terms as used herein are inclusive of motor vehicles in general, such as passenger vehicles including sports utility vehicles (SUV), buses, trucks, various commercial vehicles, watercraft including a variety of boats and ships, aircraft, and the like, and include hybrid vehicles, electric vehicles, plug-in hybrid electric vehicles, hydrogen-powered vehicles, and other alternative fuel vehicles (e.g., fuels derived from resources other than petroleum). As referred to herein, a hybrid vehicle is a vehicle that has two or more sources of power, for example, a vehicle powered by both gasoline and electricity.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

The above and other features of the present disclosure are discussed infra.

### BRIEF DESCRIPTION OF THE DRAWINGS

FIG. 1 is a block diagram to describe a system for determining whether to replace an ion filter according to an exemplary embodiment of the present disclosure;

FIG. 2 is a flowchart showing a method of determining whether a first condition and a second condition are satisfied in a method of determining whether to replace an ion filter according to an exemplary embodiment of the present disclosure;

FIG. 3 is a flowchart showing a method of determining whether a third condition is satisfied in the method of determining whether to replace an ion filter according to an exemplary embodiment of the present disclosure;

FIG. 4 is a view showing a method of deriving an expression value according to an exemplary embodiment of the present disclosure;

FIG. 5 is a graph to explain a method of determining whether to replace an ion filter according to an exemplary embodiment of the present disclosure when the performance of the ion filter decreases; and

FIG. 6 is a graph to explain a method of determining whether to replace an ion filter when there is an error in a component forming a fuel cell system according to an exemplary embodiment of the present disclosure.

It should be understood that the appended drawings are not necessarily to scale, presenting a somewhat simplified representation of various exemplary features illustrative of the basic principles of the present disclosure. The predetermined design features of the present disclosure, including, for example, predetermined dimensions, orientations, locations, and shapes, will be determined in part by the particular intended application and usage environment.

In the figures, the reference numerals refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter reference will now be made in detail to various embodiments of the present disclosure, examples of which are illustrated in the accompanying drawings and described below. However, the present disclosure may be embodied in various forms, and should not be construed as being limited to the exemplary embodiments set forth herein. Rather, the exemplary embodiments are provided so that the present disclosure will be thorough and complete, and will fully convey the scope of the present disclosure to those skilled in the art. The present disclosure is defined only by the categories of the claims. Wherever possible, the same reference numerals will be used throughout the drawings to refer to the same or like portions.

Terms such as “ . . . portion”, “ . . . unit”, “ . . . module”, etc. used in the present specification each refers to a unit that processes at least one function or operation, and may be implemented as hardware, software or a combination thereof.

It will be understood that, although the terms “first”, “second”, etc. may be used herein to describe various similar elements, these elements should not be construed as being limited by these terms. These terms are only used to distinguish one element from another.

The detailed description is merely illustrative of the present disclosure. Furthermore, the above description shows and describes exemplary embodiments of the present disclosure, but the present disclosure may be used in various other combinations, modifications, and environments. In other words, changes or modifications are possible within the scope of the idea of the present disclosure included herein, the scope equivalent to the described invention, and/or the scope of skill or knowledge in the art. The exemplary embodiments describe the best state for implementing the technical idea of the present disclosure, and various changes required for specific application fields and utilizes of the present disclosure are possible. Therefore, the detailed description of the present disclosure is not intended to limit the present disclosure to the disclosed exemplary embodiments of the present disclosure. Also, the appended claims should be construed to include other embodiments.

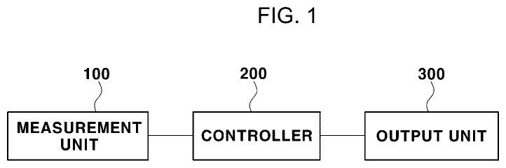

FIG. 1 is a block diagram to describe a system for determining whether to replace an ion filter according to an exemplary embodiment of the present disclosure.

Referring to FIG. 1, the system for determining whether to replace the ion filter may include a measurement unit 100, a controller 200, and an output unit 300. The system for determining whether to replace the ion filter may be applied to a thermal management system of a fuel cell. In other words, the system for determining whether to replace the ion filter may be applied to a vehicle or a system using a fuel cell stack as a power source. The thermal management system may optimally control the operating temperature of the fuel cell stack and perform a water management function by discharging heat, which is a by-product of the electrochemical reaction of the fuel cell stack, to the outside thereof. The ion filter may be used to remove ions in cooling water used in the thermal management system, and the system for determining whether to replace the ion filter may be a system for determining whether the ion filter needs to be replaced.

The measurement unit 100 may measure the insulation resistance value of the fuel cell stack while the vehicle or the system is in operation. The measurement unit 100 may be a fuel cell stack voltage management (FSVM) or a battery management system (BMS) configured for measuring the insulation resistance value of the fuel cell stack. The insulation resistance value may be measured as a number between 0 and 1,000, and generally, the insulation resistance value may be measured in hundreds of kilohms (kΩ). The period from the start of operation to the end of operation of the vehicle or the system may be defined as one cycle, and the measurement unit 100 may continuously measure the insulation resistance value within one cycle.

As an exemplary embodiment of the present disclosure, the measurement unit 100 may measure the insulation resistance of the vehicle or the system by being connected to the output terminal of the fuel cell stack. The measurement unit 100 may measure the voltage between the high-voltage terminal and the ground terminal of the fuel cell stack. Here, the high-voltage terminal may be a portion of the fuel cell stack which is not surrounded by an insulator. The measurement unit 100 may measure a composite insulation resistance which is a combination of the insulation resistance of each of the electric components connected in parallel to the high-voltage terminal and ground terminal of the fuel cell stack and the insulation resistance of cooling water. Unlike the above-described examples, the method of measuring insulation resistance may vary and may not be limited to specific embodiments.

The insulation resistance value of the fuel cell stack applied to the vehicle or the system may vary due to various causes. For example, when the internal humidity of the fuel cell stack increases, the insulation resistance value may decrease, and when the temperature of cooling water increases, the conductivity of the cooling water may increase and the insulation resistance value may decrease. Moreover, when the lifespan of the ion filter expires or the amount of ions in cooling water increases, the electrical conductivity of the cooling water may increase and the insulation resistance value may decrease. Furthermore, when a high-voltage component such as a motor, an air compressor, a pump, etc. fails or the insulation of the high-voltage component is broken, the insulation resistance value may decrease. The measured insulation resistance values may be transmitted to the controller 200.

The controller 200 may be configured to determine whether to replace the ion filter based on the insulation resistance value measured by the measurement unit 100. With one cycle from start to end of operation of the vehicle or the system, the controller 200 may be configured to determine a moving average or moving median for the average value or the median value of the insulation resistance value measured at each of cycles, and may be configured to determine whether the ion filter needs to be replaced based on at least one of the moving average, the change rate of the moving average, the movement value, or the change rate of the movement value. The moving average or moving median may be defined as a movement value. In other words, the movement value may be a moving average or moving median for the average value or the median value of the insulation resistance value. For example, the controller 200 may be a fuel control unit (FCU) configured to control various components connected to the fuel cell system.

There may be required data processing for the insulation resistance value measured to determine whether to replace the ion filter. During data processing, the average value or the median value of the insulation resistance values measured within one cycle may be determined, and the average value or the median value of the insulation resistance values may be expressed as a single digit number. In other words, the average value or the median value of the insulation resistance values coded into a single digit number may be defined as an expression value, and one expression value may be derived per one cycle. For example, a single digit number may be expressed as 0 through 5, but may not be limited thereto.

The controller 200 may be configured to determine movement values for the expression values measured in a plurality of cycles. In other words, the controller 200 may be configured to determine moving medians or moving averages for the expression values. The controller 200 may derive movement values for a preset first number of expression values and store a preset second number of movement values. The preset first number may be greater than the preset second number. For example, the preset first number may be nine and the preset second number may be five, but may not be limited thereto. The controller 200 may be configured to determine whether to replace the ion filter using the second number of movement values.

The controller 200 may be configured to determine that the ion filter needs to be replaced when at least one of three conditions is satisfied. The controller 200 may be configured to determine that the ion filter needs to be replaced only when all three conditions are satisfied.

A first condition of the three conditions may be to determine whether the size of the latest movement value of the second number of movement values is equal to or smaller than a preset threshold. The latest movement value may be a movement value derived from insulation resistance values most recently measured within one cycle by the measurement unit 100. For example, the preset threshold may be 4, but may not be limited to a specific number.

A second condition of the three conditions may be to determine whether the change rate of the second number of movement values is smaller than a preset change rate or whether a difference value between the latest movement value of the second number of movement values and a decision value based on past movement values is smaller than a preset difference value. As an exemplary embodiment of the present disclosure, the decision value may be the movement value derived from the oldest measured insulation resistance values within one cycle in the second number of movement values stored by the controller 200. As an exemplary embodiment of the present disclosure, the decision value may be an average value of movement values excluding the latest movement value in the second number of movement values stored by the controller 200. As yet another example, the decision value may be any movement value excluding the latest movement value in the second number of movement values stored by the controller 200. For example, the preset change rate and the preset difference value may be 1, but may not be particularly limited to a specific number.

A third condition of the three conditions may be to count the cases where the insulation resistance values most recently measured in one cycle are within a predetermined range and to determine whether the number of total counts is greater than a preset counting value. For example, the predetermined range may be from 86 kΩ to 140 kΩ and the preset counting value may be 40, but may not be limited thereto.

The first condition may be to determine whether the durability of the ion filter declines. The second condition may be to determine whether there is an error in the decision on the replacement of the ion filter. The second condition may be to check whether a drastic change in the insulation resistance value has occurred due to errors in components other than the ion filter. The third condition may be to directly confirm that the ion filter is not properly performing the function of removing ions because the insulation resistance value is detected to be generally small. The controller 200 may be configured to determine whether to replace the ion filter by considering all the three conditions.

The measurement unit 100 and the controller 200 each may include a processor and memory. The processor may be composed of one or more cores and may include a processor for data analysis and deep learning of a central processing unit (CPU), a general purpose graphics processing unit (GPGPU), a tensor processing unit (TPU), an application processor (AP), etc of a computing device. One or more processors may be configured for controlling to process input data depending on predefined operation rules or artificial intelligence models stored in memory. When one or more processors are artificial intelligence dedicated processors, the artificial intelligence dedicated processors may be designed to include a hardware structure specialized for processing a specific artificial intelligence model.

The processor may read the computer program or command stored in the memory and perform a process of determining whether to replace the ion filter according to the exemplary embodiment of the present disclosure. The memory may store various information required for the system for determining whether to replace the ion filter according to an exemplary embodiment of the present disclosure. For example, insulation resistance values measured by the measurement unit 100, and expression values and movement values stored by the controller 200 may be stored in the memory.

The memory may include at least one type of storage medium including a flash memory type, a hard disk type, a multimedia card micro type, a card-type memory (e.g., SD or DX memory, etc), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. Furthermore, the memory may include any type of computer-readable recording medium well-known in the art to which the present disclosure pertains. The description of the memory described above is merely an example, and the present disclosure is not limited thereto.

The output unit 300 may display to the driver whether the ion filter needs to be replaced. When the controller 200 determines that the ion filter needs to be replaced, the output unit 300 may notify the driver through a message, warning light, and warning sound. Moreover, the output unit 300 may also output a message, warning light, and warning sound when notifying that there is a problem in the fuel cell system in which the insulation resistance value is equal to or smaller than a predetermined level.

According to an exemplary embodiment of the present disclosure, whether to replace the ion filter is determined depending on whether the measured insulation resistance values and post-processed data of the insulation resistance values satisfy the three conditions, precisely determining whether the ion filter needs to be replaced without having to use an electrical conductivity sensor.

According to an exemplary embodiment of the present disclosure, the controller 200 may distinguish a case where a drastic change in insulation resistance value is occurred due to an error in a component other than the ion filter, increasing reliability of decision on replacement of the ion filter.

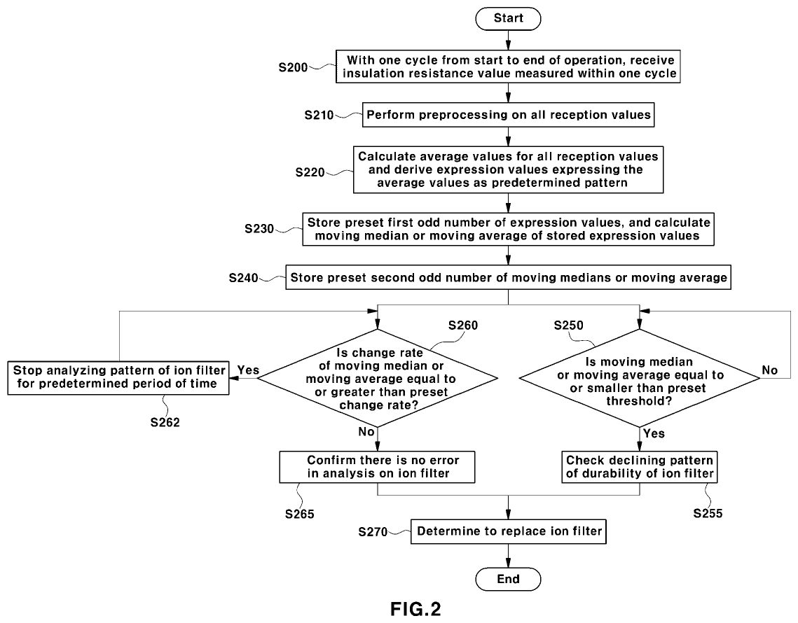

FIG. 2 is a flowchart showing a method of determining whether the first condition and the second condition are satisfied in the method of determining whether to replace the ion filter according to an exemplary embodiment of the present disclosure.

Referring to FIG. 1 and FIG. 2, with one cycle from start to end of the operation of the vehicle or the system, the measurement unit 100 may continuously measure the insulation resistance value within one cycle. The start and end of operation may be the vehicle's engine or system being turned on or off. Insulation resistance values may be measured at preset time intervals. However, when the number of insulation resistance values measured within one cycle is smaller than a preset number of times, the measurement unit 100 may not store the insulation resistance values measured within the corresponding cycle. Furthermore, when the number of insulation resistance values measured within one cycle is smaller than the preset number of times, the controller 200 may not use the insulation resistance values measured within the cycle in a process of determining replacement of the ion filter. For example, the preset number of times may be 40, but may not be limited thereto. When the number of insulation resistance values measured within one cycle is smaller than the preset number of times, this means that the operation time of the vehicle or the system is short. Therefore, to prevent errors which may occur when determining replacement of the ion filter based on relatively little data measured within the short operation time, the controller 200 may not use the insulation resistance values measured within the cycle in a process of determining replacement of the ion filter (S200).

The insulation resistance values measured by the measurement unit 100 may be transmitted to the controller 200. The controller 200 may perform preprocessing on all reception values received from the measurement unit 100. The controller 200 may remove a null value and an error value from the measured insulation resistance values (S210).

The controller 200 may be configured to determine an average value or a median value of all reception values and derive an expression value that expresses the average value or the median value in a predetermined pattern. The controller 200 may be configured to determine the average value or the median value of the insulation resistance values measured in one cycle and derive expression values in which the average value or the median value is coded as a single digit number.

As an exemplary embodiment of the present disclosure, the expression value may be expressed as 0 through 5. The controller 200 may derive an expression value for each of cycles, and five expression values may be converted into one 5-digit number (unit of 10,000) and stored in one 16-bit variable, which is a 2-byte storage space. The maximum value of a number expressed as a 16-bit variable may be 65535. Because the expression value cannot be expressed as a number greater than 5, the 5-digit number converted from the five expression values is definitely smaller than 65535. Therefore, the expression values derived from each of five cycles are stored as one number, minimizing the storage space for storing data.

As an exemplary embodiment of the present disclosure, the expression values may be expressed as 0 through 3. The controller 200 may derive an expression value for each of cycles, and four expression values may be converted into one 10-digit number (unit of 1,000,000,000) and stored in one 32-bit variable, which is a 2-byte storage space. The maximum value of a number expressed as a 32-bit variable may be 4,294,967,295.

As yet another example, the expression values may be expressed as 0 to 1. The controller 200 may derive an expression value for each of cycles, and two expression values may be converted into one 20-digit number (unit of 10,000,000,000,000,000,000) and stored in one 64-bit variable, which is a 2-byte storage space. The maximum value of a number expressed as a 64-bit variable may be 18,446,744,073,709,551,615 (S220).

The controller 200 may store preset first number of expression values. The controller 200 may delete an oldest expression value when a new expression value is determined. For example, the preset first number may be nine, but may not be limited thereto. The controller 200 may be configured to determine the movement value of the stored first number of expression values. In other words, the controller 200 may be configured to determine the moving median or moving average of the first number of expression values. For example, when the movement value is a moving median, the controller 200 may be configured to determine a medium-sized expression value in the first number of expression values as a moving median, and may use an odd number of expression values to use the moving median rather than using the average value (S230).

The controller 200 may store preset second number of movement values. In other words, the controller 200 may store preset second number of moving medians or moving averages. The controller 200 may delete an oldest movement value when anew movement value is determined. For example, the preset second number may be five, but not limited thereto (S240).

The controller 200 may compare the size of one of the movement values with a preset threshold to check declining pattern of the durability of the ion filter. In other words, the controller 200 may compare the size of one of the moving averages or the size of one of the moving medians with a preset threshold to check declining pattern of the durability of the ion filter. The controller 200 may be configured to determine whether the latest movement value is equal to or smaller than the preset threshold. For example, the preset threshold may be 4, but not limited thereto. When the latest movement value is greater than the preset threshold, the controller 200 may be configured to determine that the durability of the ion filter does not include a declining pattern. Therefore, the controller 200 may continue to compare the size of the latest movement value with a preset threshold by processing the insulation resistance values measured by the measurement unit 100. Unlike the above-described example, the controller 200 may compare the average value of the movement values with the preset threshold to check declining pattern of the durability of the ion filter (S250).

When the latest movement value is equal to or smaller than the preset threshold, the controller 200 may be configured to determine that the durability of the ion filter includes a declining pattern. In other words, when the latest movement value is smaller than the preset threshold, the controller 200 may be configured to determine that the ion filter is not performing its original function (S255).

To check whether there is an error in the determination process on the ion filter, the controller 200 may compare the change rate of the movement values with the preset change rate. In other words, to check whether there is an error in the determination process on the ion filter, the controller 200 may compare the change rate of the moving medians or the change rate of the moving averages with the preset change rate. The controller 200 may be configured to determine whether the change rate of the movement values is smaller than the preset change rate or whether the difference value between the latest movement value of the second number of movement values and the decision value based on past movement values is smaller than the preset difference value. For example, the preset change rate and the preset difference value may be 1, but may not be particularly limited to a specific number. The reason for checking the change rate of the movement values is that a drastic change in the insulation resistance value may be a change caused by components or factors other than the ion filter (S260).

When the change rate of the movement values is greater than or equal to the preset change rate or the difference value between the latest movement value and the decision value is greater than or equal to the preset difference value, the controller 200 may be configured to determine that there is a drastic change in the insulation resistance value due to factors other than the ion filter, and may stop analyzing the pattern of the ion filter for a predetermined time period. For example, the predetermined time period may be about 20 cycles when the start and end of operation of the vehicle or the system is considered one cycle, but may not be particularly limited thereto. However, even in the predetermined time period, the measurement unit 100 may continue to measure the insulation resistance value. The reason for not analyzing the pattern of the ion filter for a predetermined time period is because data measured during the time until the driver completes inspecting the vehicle or the system based on the warning message output by the output unit 300 in response to the drastic change in the insulation resistance value may be erroneous. After the predetermined time period has elapsed, the controller 200 may again compare the change rate of the movement values with the preset change rate or the difference value between the latest movement value and the decision value with the preset difference value (S262).

When the change rate of the movement values is smaller than the preset change rate or the difference value between the latest movement value and the decision value is smaller than the preset difference value, the controller 200 may confirm that there is no error in analysis on the ion filter. In other words, because there is no drastic change in the insulation resistance value, the controller 200 may be configured to determine that the result of analyzing the durability pattern of the ion filter is reliable (S265).

When the controller 200 checks declining pattern of the durability of the ion filter and confirms that there is no error in analysis on the ion filter, the controller 200 may be configured to determine that the ion filter needs to be replaced. When both the first condition to check declining pattern of the durability of the ion filter and the second condition to confirm that there is no error in analysis on the ion filter are satisfied, the controller 200 may be configured to determine that the ion filter needs to be replaced. The second condition may be to check whether the result of analysis on the declining pattern of durability of the ion filter based on the first condition is reliable (S270).

According to an exemplary embodiment of the present disclosure, whether to replace the ion filter is determined after confirming declining pattern of the durability of the ion filter and going through a process to verify the reliability of the declining pattern of the durability of the ion filter, increasing reliability of decision on replacement of the ion filter.

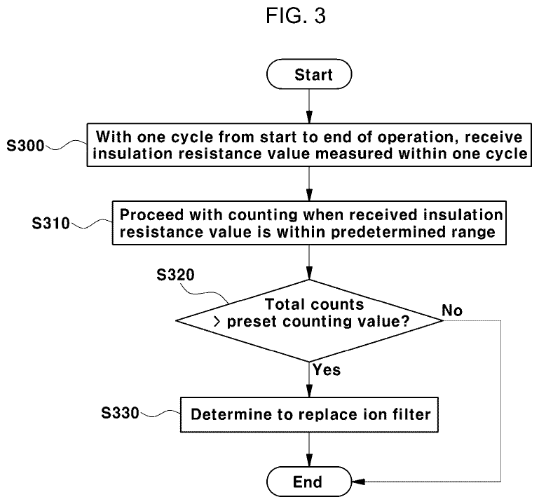

FIG. 3 is a flowchart showing a method of determining whether the third condition is satisfied in the method of determining whether to replace the ion filter according to an exemplary embodiment of the present disclosure.

Referring to FIG. 1 and FIG. 3, with one cycle from start to end of the operation of the vehicle or the system, the measurement unit 100 may measure the insulation resistance value within one cycle. The insulation resistance values measured by the measurement unit 100 may be transmitted to the controller 200 (S300).

The controller 200 may proceed with counting when the received insulation resistance value is within a predetermined range. For example, the predetermined range may be from 86 kΩ to 140 kΩ, but may not be particularly limited thereto. When the insulation resistance values measured in one cycle are equal to or smaller than a preset number, the controller 200 may not determine whether to replace the ion filter based on the insulation resistance values measured in the one cycle. For example, the preset number may be 40, but may not be limited thereto (S310).

The controller 200 may count the cases where the insulation resistance values most recently measured in one cycle are within a predetermined range and may be configured to determine whether the number of total counts is greater than a preset counting value. In other words, the third condition may be to count the cases where the insulation resistance values most recently measured in one cycle are within a predetermined range and to determine whether the number of total counts is greater than the preset counting value. For example, the preset counting value may be 40, but may not be particularly limited to a specific number. When the number of total counts is equal to or smaller than the preset counting value, the controller 200 may confirm that there is no error in the insulation resistance values within the corresponding cycle and end the process of determining whether to replace the ion filter. However, in the next cycle, the controller 200 may be configured to determine whether the insulation resistance values are within a predetermined range (S320).

When the number of total counts is greater than the preset counting value, the controller 200 may confirm that there is an error in the insulation resistance values within the corresponding cycle and decide that the ion filter needs to be replaced. As an exemplary embodiment of the present disclosure, the controller 200 may compare the insulation resistance values measured in each of consecutive cycles, which is two or more cycles and not one cycle, with the predetermined range to determine whether the third condition is satisfied. The controller 200 may be configured to determine whether a total count of cases, the case in which the insulation resistance values measured in each of the consecutive cycles are within the predetermined range, is greater than the preset counting value. Here, the plurality of cycles may be two to four consecutive cycles, but may not be limited thereto. The controller 200 checks whether the third condition is satisfied in all the plurality of cycles, preventing errors in determining replacement of the ion filter. In response that all of the first condition, the second condition, and the third condition are satisfied, the controller 200 may be configured to determine that the ion filter needs to be replaced. However, when any one of or at least two of the first condition, second condition and third condition are satisfied, the controller 200 may be configured to determine that the ion filter needs to be replaced (S330).

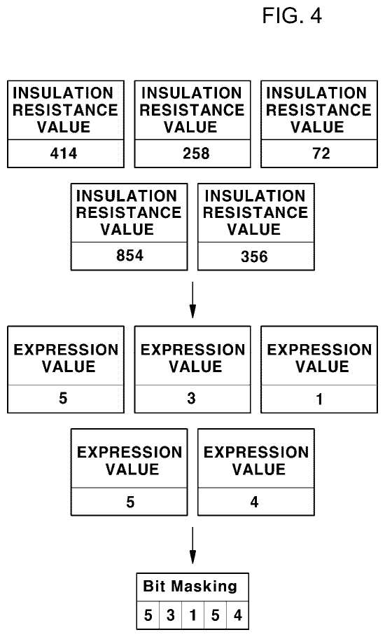

FIG. 4 is a view showing a method of deriving an expression value according to an exemplary embodiment of the present disclosure. FIG. 4 is a diagram to explain the case where the variable of the controller is 16 bits.

Referring to FIG. 1 and FIG. 4, the controller 200 may perform data processing on a plurality of insulation resistance values measured by the measurement unit 100. The controller 200 may code the insulation resistance values measured using bit masking to minimize data storage space. The controller 200 may express the average value or the median value of the insulation resistance values measured within one cycle as a single digit number. The value expressed as a single digit number may be defined as an expression value. For example, a single digit number may be 0 through 5.

As an exemplary embodiment of the present disclosure, the controller 200 may derive the expression value by rounding the average value or the median value of the insulation resistance value to hundreds but limiting the maximum value thereof to 5. When the average value or the median value of the insulation resistance value is 258, the expression value may be expressed as 3. When the average value or the median value of the insulation resistance value is 72, the expression value may be expressed as 1. When the average value or the median value of the insulation resistance value is 854, the expression value may be expressed as 5, which is set as a maximum value. When the average value or the median value of the insulation resistance value is 356, the expression value may be expressed as 4. The average or median values of the insulation resistance value measured in five cycles may be expressed as 5, 3, 1, 5, 4, and the five expression values may be converted into one 5-digit number and stored in one 16-bit variable, which is a 2-byte storage space. In other words, the average or median values of insulation resistance value measured in five cycles may be stored as one number, 53154.

In a process of processing the stored expression values, the controller 200 may interpret the five stored expression values by dividing the value stored as one number into 10000, 1000, 100, and 10, respectively. For example, when dividing 53154 by 10000, the quotient is 5 and the remainder is 3154. When dividing the remainder of 3154 by 1000, the quotient is 3 and the remainder is 154. When dividing the remainder of 154 by 100, the quotient is 1 and the remainder is 54. When dividing the remainder of 54 by 10, the quotient is 5 and the remainder is 4. Through the present process, the controller 200 may interpret the value stored as one number as the originally stored expression value of 5, 3, 1, 5, 4.

According to an exemplary embodiment of the present disclosure, the five expression values are stored as one number, minimizing the storage space for storing data.

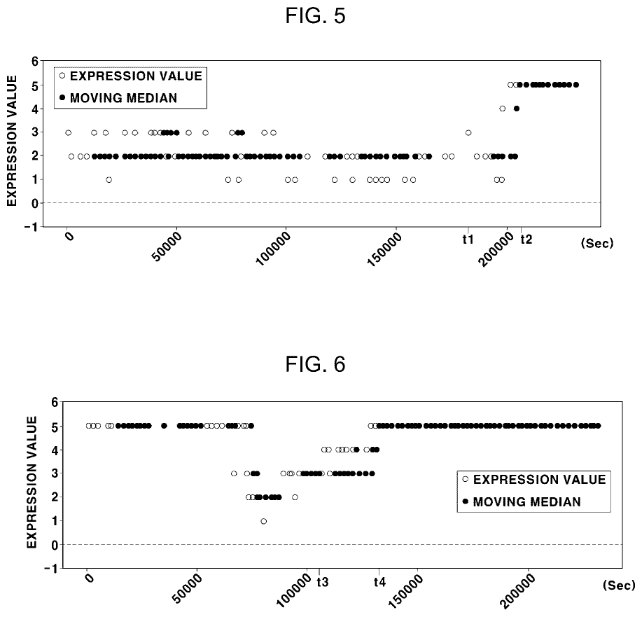

FIG. 5 is a graph to explain the method of determining whether to replace the ion filter according to an exemplary embodiment of the present disclosure when the performance of the ion filter decreases.

Referring to FIG. 2 and FIG. 5, with one cycle from the start to the end of operation of the vehicle or the system, the controller may derive an expression value for each cycle. The controller may derive one movement value from nine expression values. FIG. 5 explains the case where the movement value is a moving median.

Because the vehicle or the system operates constantly, the durability of the ion filter may decrease. In the exemplary embodiment of the present disclosure, the expression values may be expressed as a digit of 1 through 3, and the moving median may be expressed as 2 or 3. The controller may confirm any one of the second number of moving medians stored at a first time point t1 or the size of the latest moving median is equal to or smaller than 4, which is a preset threshold. In other words, the controller may be configured to determine that the durability of the ion filter shows a declining pattern. Moreover, the controller may confirm that the change rate of the moving medians or the difference between the latest moving median and the oldest moving median in the second number of moving medians stored at the first time point t1 is smaller than 1, which is a preset difference value. The present exemplary embodiment explains the case where the decision value is the oldest moving median in the moving medians. The controller may be configured to determine that the declining pattern of the durability of the ion filter is a reliable result. The moving median is usually expressed as 2 after a predetermined time period has passed because the vehicle or the system was first driven. Therefore, the controller may be configured to determine that replacement of the ion filter is necessary because the first and second conditions are satisfied and the declining pattern of durability of the ion filter is confirmed.

A second time point t2 may be a time point after the ion filter is replaced. The controller may confirm any one of the second number of moving medians stored at the second time point t2 or the size of the latest moving median is greater than 4, which is a preset threshold. Therefore, the controller may decide that there is no need to replace the ion filter.

FIG. 6 is a graph to explain the method of determining whether to replace the ion filter when there is an error in a component forming a fuel cell system according to an exemplary embodiment of the present disclosure.

Referring to FIG. 2 and FIG. 3, with one cycle from the start to the end of operation of the vehicle or the system, the controller may derive an expression value for each cycle. The controller may derive one movement value from nine expression values. FIG. 6 explains the case where the movement value is a moving median.

When a failure occurs in a high-voltage component applied to the fuel cell system, the insulation resistance may decrease even though there is no problem in the durability of the ion filter. In the exemplary embodiment of the present disclosure, the expression values and moving median are generally expressed as 5, and around a third time point t3, the expression value and moving median are expressed as 2 through 4. In other words, the insulation resistance value may drastically change at the third time point t3. The controller may confirm any one of the second number of moving medians stored at the third time point t3 or the size of the latest moving median is equal to or smaller than 4, which is a preset threshold. In other words, the controller may be configured to determine that the durability of the ion filter shows a declining pattern. However, the controller may confirm that the change rate of the moving medians or the difference between the latest moving median and the oldest moving median in the second number of moving medians stored at the third time point t3 is greater than or equal to 1, which is a preset difference value. In other words, the controller may confirm that there is an error in confirming the declining pattern of the durability of the ion filter. Thereafter, the controller may stop analyzing the pattern of the ion filter for a predetermined time period. When starting again to analyze the pattern, the controller may confirm any one of the second number of moving medians stored at a fourth time point t4 or the size of the latest moving median is greater than 4, which is a preset threshold. That the pattern of the ion filter is confirmed to be normal at the fourth time point t4 may mean that the problem in components other than the ion filter has been resolved between the third time point t3 and the fourth time point t4.

As is apparent from the above description, the present disclosure provides the following effects.

According to an exemplary embodiment of the present disclosure, whether to replace an ion filter is determined depending on whether measured insulation resistance values and post-processed data of the insulation resistance values satisfy three conditions, precisely determining whether the ion filter needs to be replaced without having to use an electrical conductivity sensor.

According to an exemplary embodiment of the present disclosure, a controller may distinguish a case where a drastic change in insulation resistance value is occurred due to an error in a component other than an ion filter, increasing reliability of decision on replacement of the ion filter.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A system for determining whether to replace an ion filter, the system comprising:
a measurement unit configured for measuring an insulation resistance value of a fuel cell stack while a vehicle or a system is in operation; and
a controller operatively connected to the measurement unit and configured to determine whether to replace the ion filter based on the insulation resistance value,
wherein
with one cycle from start to end of operation of the vehicle or the system, the controller is configured to determine a movement value based on the insulation resistance value measured at each of cycles,
the movement value is a moving average or a moving median for an average value or a median value of the insulation resistance value, and
the controller is configured to determine whether to replace the ion filter based on at least one of a size of the movement value or a change rate of the movement value.

2. The system of claim 1,
wherein the controller is configured to determine whether a first condition for determining whether the size of the movement value is equal to or smaller than a preset threshold is satisfied and whether a second condition for determining whether the change rate of the movement value is smaller than a preset change rate is satisfied, and
wherein in response that all of the first condition and the second condition are satisfied, the controller is configured to conclude that the ion filter needs to be replaced.

3. The system of claim 2,
wherein the controller is configured to count cases where the insulation resistance values measured in one cycle from the start to the end of operation of the vehicle or the system are within a predetermined range, and is configured to determine whether a third condition for determining whether a total count is greater than a preset counting value is satisfied, and
wherein in response that all of the first condition, the second condition, and the third condition are satisfied, the controller is configured to conclude that the ion filter needs to be replaced.

4. The system of claim 3, wherein, in response that the insulation resistance values measured in one cycle are equal to or smaller than a preset number, the controller does not determine whether the third condition is satisfied based on the insulation resistance values measured in the corresponding one cycle.

5. The system of claim 4, wherein the controller is configured to determine whether the total count of cases, the case in which the insulation resistance values measured at each of consecutive cycles are within the predetermined range, is greater than the preset counting value.

6. The system of claim 1, wherein the movement value is determined based on expression values in which the average value or the median value of the insulation resistance values measured within one cycle is coded as a single digit number.

7. The system of claim 6, wherein
five expression values are stored by being converted into one 5-digit number,
ten expression values are stored by being converted into one 10-digit number, or
nineteen expression values are stored by being converted into one 19-digit number.

8. The system of claim 6, wherein
the expression values are stored in a preset first number,
the controller is configured to determine the movement value based on the expression values stored in the preset first number,
the controller is configured to determine whether to replace the ion filter based on a consecutive preset second number of the movement values, and
the preset first number is greater than the preset second number.

9. The system of claim 8, wherein the controller is configured to compare a latest movement value in the preset second number of the movement values or a size of an average of the movement values with a preset threshold to determine whether a first condition is satisfied.

10. The system of claim 9, wherein the controller is configured to compare a difference between the latest movement value in the preset second number of the movement values and a decision value based on past movement values with a preset difference value to determine whether a second condition is satisfied.

11. The system of claim 10, wherein, in response that the difference between the latest movement value and the decision value is greater than the preset difference value, the controller is configured to confirm that there is an error in measurement of the insulation resistance value and stops a process of determining whether to replace the ion filter for a predetermined time period.

12. The system of claim 9, wherein the controller is configured to compare a change rate of the preset second number of the movement values with a preset change rate to determine whether a second condition is satisfied.

13. The system of claim 12, wherein the controller is configured to conclude the ion filter needs to be replaced only in response that all of the first condition and the second condition are satisfied.

14. A method of determining whether to replace an ion filter implemented by a controller configured to determine whether to replace the ion filter, the method comprising:
determining, by the controller, an average value or a median value of insulation resistance values measured in one cycle from start to end of operation of a vehicle or a system;
deriving, by the controller, a plurality of expression values in which the average value or the median value of the insulation resistance values measured at each of cycles is coded as a single digit number;
determining, by the controller, a plurality of movement values for the expression values; and
determining, by the controller, whether to replace the ion filter based on at least one of a size of at least one of the movement values or a change rate of the movement values,
wherein the movement value is a moving average or a moving median for an average value or a median value of the insulation resistance values.

15. The method of claim 14, wherein the determining of whether to replace the ion filter includes:
determining whether a first condition for determining whether the size of the movement value is equal to or smaller than a preset threshold is satisfied and whether a second condition for determining whether the change rate of the movement value is smaller than a preset change rate is satisfied, and
concluding, in response that all of the first condition and the second condition are satisfied, that the ion filter needs to be replaced.

16. The method of claim 15, wherein the determining of whether to replace the ion filter includes:
counting cases where the insulation resistance values measured in one cycle from the start to the end of operation of the vehicle or the system are within a predetermined range, and determining whether a third condition for determining whether a total count is greater than a preset counting value is satisfied, and
concluding, in response that all of the first condition, the second condition, and the third condition are satisfied, that the ion filter needs to be replaced.

17. The method of claim 14, wherein the determining of the movement values includes:
determining the movement value based on a preset first number of the expression values; and
determining whether to replace the ion filter based on a consecutive preset second number of the movement values.

18. The method of claim 17, further including comparing a latest movement value in the preset second number of the movement values or a size of an average of the movement values with a preset threshold to determine whether a first condition is satisfied.

19. The method of claim 18, further including comparing a difference between the latest movement value in the preset second number of the movement values and a decision value based on past movement values with a preset difference value or comparing a change rate of the preset second number of the movement values with a preset change rate to determine whether a second condition is satisfied.

20. A storage medium configured to store computer-readable instructions, wherein the instructions are executed by a processor, and wherein the processor is configured to perform operations of:
determining an average value or a median value of insulation resistance values measured in one cycle from start to end of operation of a vehicle or a system;
deriving a plurality of expression values in which the average value or the median value of the insulation resistance values measured at each of cycles is coded as a single digit number;
determining movement values for the expression values; and
determining whether to replace the ion filter based on at least one of a size of at least one of the movement values or a change rate of the movement values,
wherein the movement value is a moving average or a moving median for an average value or a median value of the insulation resistance values.
